(19) United States
(12) Patent Application Publication
(10) Pub. No.: US 2012/0045621 A1
(43) Pub. Date: Feb. 23, 2012

(54) COATING, ARTICLE COATED WITH COATING, AND METHOD FOR MANUFACTURING ARTICLE

(75) Inventors: HSIN-PEI CHANG, Tu-Cheng (TW); WEN-RONG CHEN, Tu-Cheng (TW); HUAN-WU CHIANG, Tu-Cheng (TW); CHENG-SHI CHEN, Tu-Cheng (TW); JUAN ZHANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/966,024

(22) Filed: Dec. 13, 2010

(30) Foreign Application Priority Data
Aug. 19, 2010 (CN) 201010257391.7

(51) Int. Cl. B32B 3/30; C23C 14/35; B32B 9/04

(52) U.S. Cl. 428/172; 428/156; 204/192.15

(57) ABSTRACT

A coating includes a anti-fingerprint layer. The anti-fingerprint layer comprises zinc oxide-aluminum oxide, the anti-fingerprint layer comprises a plurality of nano scale concavities therein.

### CROSS-REFERENCE TO RELATED APPLICATIONS

The present application is related to co-pending U.S. patent application (Attorney Docket No. US34384), entitled “COATING, ARTICLE COATED WITH COATING, AND METHOD FOR MANUFACTURING ARTICLE”, by Zhang et al. This application has the same assignee as the present application and has been concurrently filed herewith. The above-identified application is incorporated herein by reference.

### BACKGROUND

1. Technical Field

The exemplary disclosure generally relates to coatings, and particularly relates to articles coated with the coatings and method for manufacturing the articles.

2. Description of Related Art

With the development of wireless communication and information processing technology, portable electronic devices, such as mobile telephones and electronic notebooks are now in widespread use. External appearance of the housing of the portable electronic device is one of the key factors for attracting consumers. However, typical housings can be easily marred by fingerprints.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coating, article coated with the coating and method for manufacturing the article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coating.

FIG. 2 is a top view of the coating in FIG. 1.

FIG. 3 is a cross-sectional view of an article coated with the coating in FIG. 1.

FIG. 4 is a diagram for manufacturing the article in FIG. 2.

FIG. 5 is a schematic view of a magnetron sputtering coating machine for manufacturing the article in FIG. 2.

### DETAILED DESCRIPTION

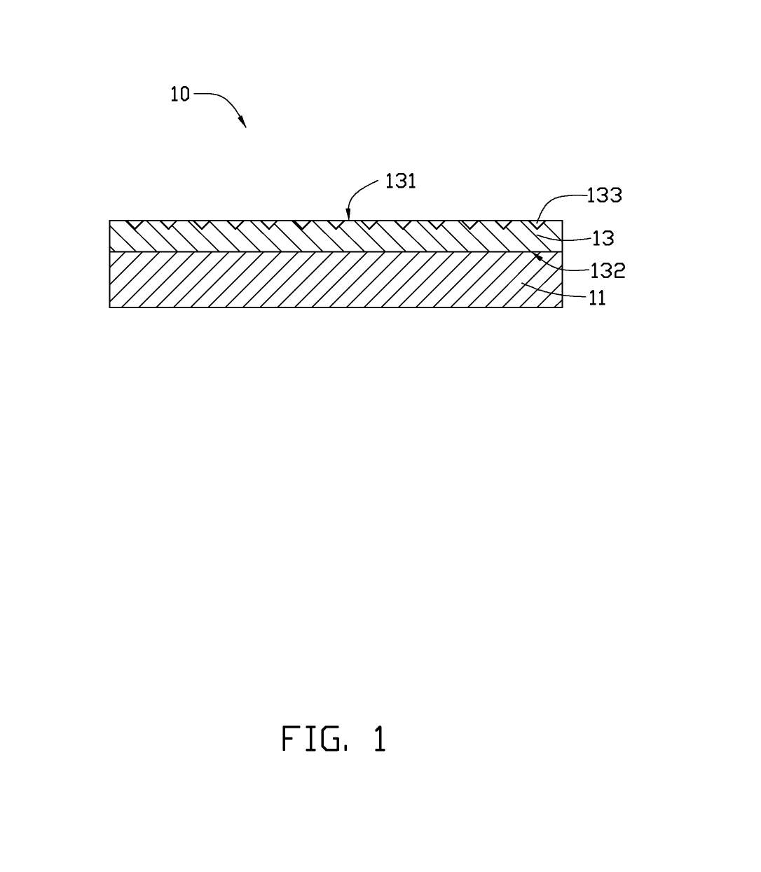

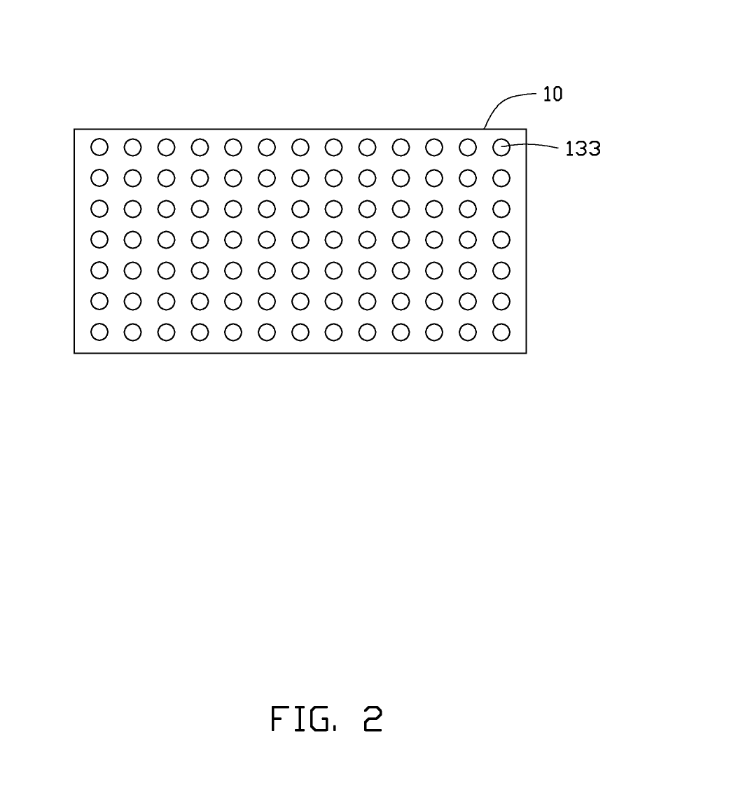

Referring to FIGS. 1 and 2, a coating 10 includes an anti-fingerprint layer 13. The anti-fingerprint layer 13 comprises zinc oxide-aluminum oxide (ZnO-Al2O3). The anti-fingerprint layer 13 may be deposited by magnetron sputtering or cathodic arc deposition. The anti-fingerprint layer 13 has a thickness ranging from about 0.03 micrometer to about 1 micrometer.

The anti-fingerprint layer 13 includes an outer surface 131 and an opposite inner surface 132. The anti-fingerprint layer 13 comprises a plurality of nano scale concavities 133 in the outer surface 131 so that the outer surface 131 is alternately concave and convex. The concavities 133 may be used for accommodating air around the anti-fingerprint layer 13, to form a gaseous film on the outer surface 131. The gaseous film can prevent grease and/or dirt from attaching to the anti-fingerprint layer 13, providing good fingerprint resistance attribute to the anti-fingerprint layer 13. It is to be understood that the coating 10 may include a decorative color layer 11 deposited on the inner surface 132.

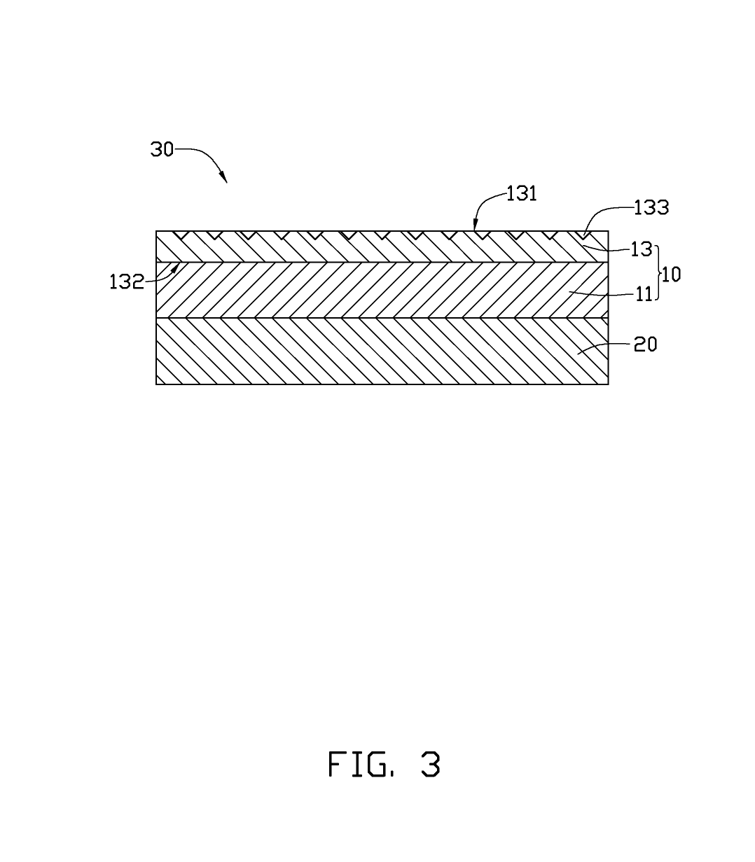

Referring to FIG. 3, an exemplary article 30 includes a substrate 20 and the coating 10 deposited on the substrate 20. The substrate 20 may be made of metallic materials, such as high speed steel, aluminum, aluminum alloy, copper, copper alloy or magnesium alloy. The substrate 20 also may be made of non-metallic materials, such as plastic, ceramic, glass, or polymer. The article 30 may be a housing of an electronic device.

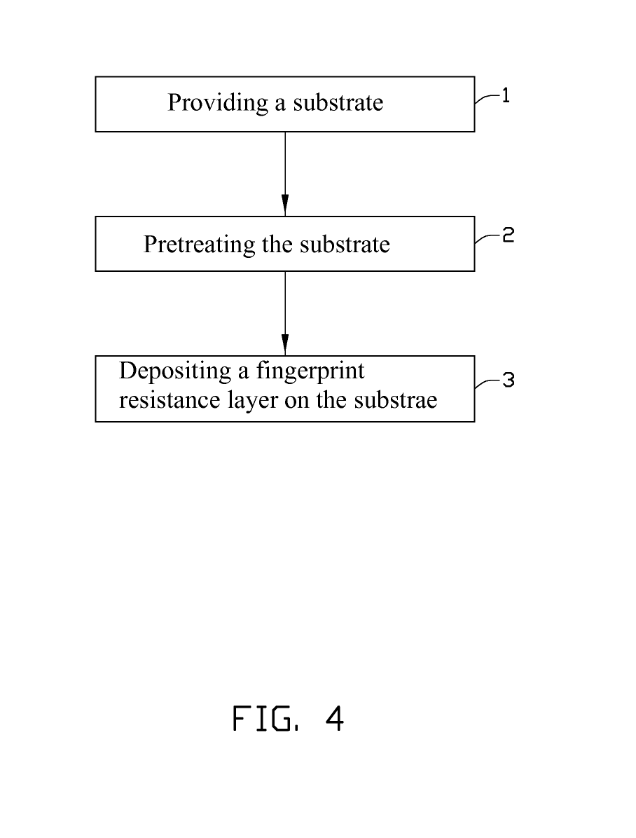

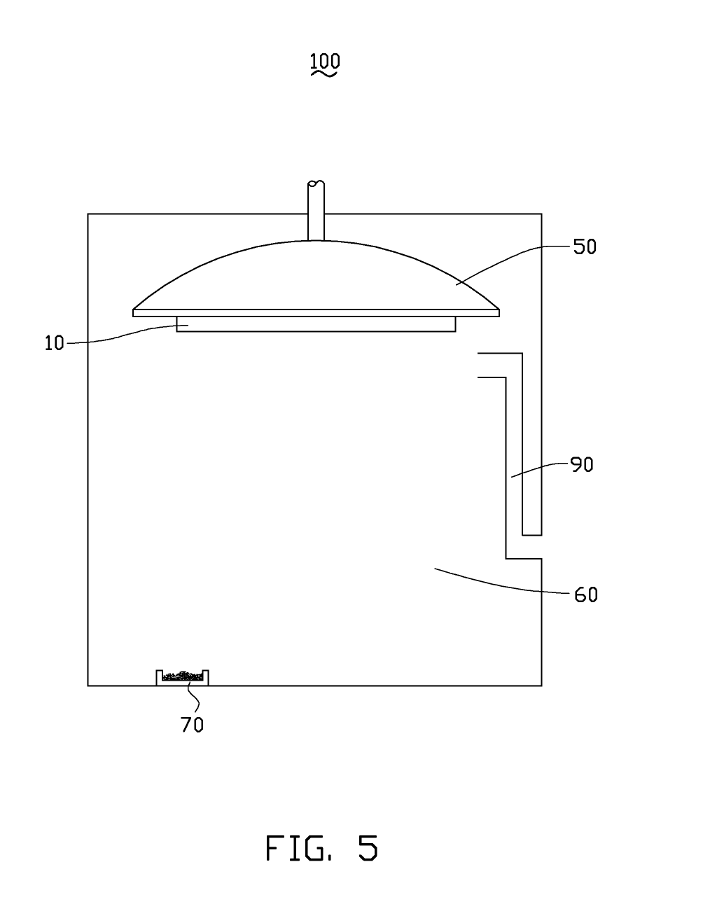

Referring to FIGS. 4 and 5, a method for manufacturing the article 30 includes at least the following steps:

Step 1 is providing the substrate 20. The substrate 20 may be made of metallic materials, such as high speed steel, aluminum, aluminum alloy, copper, copper alloy or magnesium alloy. The substrate 20 also may be made of non-metallic materials, such as plastic, ceramic, glass, or polymer.

Step 2 is pretreating the substrate 20. Firstly, the substrate 20 is washed with a solution (e.g., alcohol or acetone) in an ultrasonic cleaner to remove, e.g., grease, dirt, and/or impurities. Secondly, the substrate 20 is dried. Thirdly, the substrate 20 is retained on a rotating bracket 50 in a vacuum chamber 60 of a magnetron sputtering coating machine 100. The vacuum level of the vacuum chamber 60 is about 8.0×10−3 Pa, and pure argon is pumped into the vacuum chamber 60 at a flux of about 300 standard cubic centimeters per minute (sscm) to 500 sccm from a gas inlet 90 for about 2-8 minutes, which washes the substrate 20 to further remove the grease or dirt. Thus, a binding ability between the substrate 20 and the anti-fingerprint layer 13 is enhanced.

Step 3 is depositing the anti-fingerprint layer 13 on the substrate 20. The temperature in the vacuum chamber 60 is about 20˜300° C.; the speed of the rotating bracket 50 is about 1 to 3 revolutions per minute (rpm); nitrogen is pumped into the vacuum chamber 60 at a flux of about 10 sccm to about 300 sccm and an oxygen is pumped into the vacuum chamber 60 at a flux of about 10 sccm to about 100 sccm from the gas inlet 90; a zinc-aluminum composite alloy target 70 is evaporated; a bias voltage applied to the substrate 20 is in a range of −100 to −300 volts for about 20 to 60 min by depositing the anti-fingerprint layer 13 on the substrate 20. The zinc-aluminum composite alloy contains aluminum in a range of about 50 to about 95 wt %.

It is to be understood that the color layer 11 may be deposited on the anti-fingerprint layer 13, to improve the appearance of the article 30.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coating, comprising:
an anti-fingerprint layer comprising zinc oxide-aluminum oxide, the anti-fingerprint layer defining a plurality of nano scale concavities therein.

2. The coating as claimed in claim 1, wherein the anti-fingerprint layer has a thickness ranging from about 0.03 micrometer to about 1 micrometer.

3. The coating as claimed in claim 1, wherein the anti-fingerprint layer comprises an outer surface and an opposite inner surface; the nano scale concavities are defined in the outer surface.

4. The coating as claimed in claim 3, further comprising a color layer deposited on the inner surface to decorate the appearance of the coating.

5. The coating as claimed in claim 3, wherein the nano scale concavities are formed so that the outer surface is formed with an interface structure having alternating concave and convex portions, the convex portions for accommodating air around the anti-fingerprint layer.

6. An article, comprising:
a substrate; and
a coating deposited on the substrate, the coating including a anti-fingerprint layer;
wherein the anti-fingerprint layer comprises zinc oxide-aluminum oxide, the anti-fingerprint layer comprises a plurality of nano scale concavities therein.

7. The article as claimed in claim 6, wherein the anti-fingerprint layer has a thickness ranging from about 0.03 micrometer to about 1 micrometer.

8. The article as claimed in claim 6, wherein the anti-fingerprint layer comprises an outer surface and an opposite inner surface; the nano scale concavities are defined in the outer surface.

9. The article as claimed in claim 8, further comprising a color layer deposited on the inner surface to decorate the appearance of the coating.

10. The article as claimed in claim 8, wherein the nano scale concavities are formed so that the outer surface is alternately concave and convex, the convex configured for accommodating air around the anti-fingerprint layer.

11. The article as claimed in claim 6, wherein the substrate comprises metallic material.

12. The article as claimed in claim 11, wherein the metallic material is high speed steel, aluminum, aluminum alloy, copper, copper alloy or magnesium alloy.

13. The article as claimed in claim 6, wherein the substrate comprises non-metallic material.

14. The article as claimed in claim 13, wherein the non-metallic material is plastic, ceramic, glass, or polymer.

15. A method for manufacturing an article comprising steps of:
providing a substrate; and
depositing a coating on the substrate, the coating including a anti-fingerprint layer;
wherein the anti-fingerprint layer comprises zinc oxide-aluminum oxide, the anti-fingerprint layer defines a plurality of nano scale concavities therein.

16. The method of claim 15, wherein when depositing the coating on the substrate, the substrate is retained in a vacuum chamber of a magnetron sputtering coating machine; the temperature in the vacuum chamber is about 20˜300° C.; nitrogen is pumped into the vacuum chamber at a flux of about 10 sccm to about 300 sccm and an oxygen is pumped into the vacuum chamber at a flux of about 10 sccm to about 100 sccm; a zinc aluminum composite alloy target is evaporated; a bias voltage of about −100 to −300 volts is applied to the substrate for about 20 to 60 min.

17. The method of claim 16, wherein the zinc aluminum composite alloy contains aluminum in a range of about 50 to about 95 wt %.

18. The method of claim 15, further including pretreating the substrate in a washing step in which the substrate is washed with a solution in an ultrasonic cleaner.

19. The method of claim 18, wherein pretreating the substrate further includes a drying step.

20. The method of claim 19, wherein pretreating the substrate further includes a Plasma Cleaning step in which: the substrate is retained on a rotating bracket in a vacuum chamber of a magnetron sputtering coating machine; the vacuum level of the vacuum chamber is about 8.0×10−3 Pa, and pure argon is pumped into the vacuum chamber at a flux of about 300 sccm to 500 sccm for about 2-8 minutes.
